(19) United States
(12) Patent Application Publication
(10) Pub. No.: US 2025/0113555 A1
(43) Pub. Date: Apr. 3, 2025

(54) SEMICONDUCTOR STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/822,406

(22) Filed: Sep. 2, 2024

(30) Foreign Application Priority Data
Sep. 28, 2023 (CN) 202322663100.X

(51) Int. Cl. H01L 29/06; H01L 29/778

(52) U.S. Cl. CPC H10D 62/102; H10D 62/124; H10D 30/47

(57) ABSTRACT

A semiconductor structure includes a substrate including a first region, a second region and a third region located between the first region and the second region; a channel structure formed on the substrate; and a first P-type buried layer located in the third region. The first P-type buried layer extends along a direction parallel to a channel width. In the semiconductor structure, the first P-type buried layer is disposed in the substrate, and is configured to deplete the two-dimensional electron gas in the channel structure so as to achieve an enhancement-mode semiconductor structure. With this disposure, the problems of gate leakage, the electric field concentration effect of the gate close to the edge of the drain and the like are avoided, and tedious steps of manufacturing a P-type semiconductor layer above a channel structure in conventional method is avoided, which simplifies the manufacturing method, and effectively improves the production efficiency.

### CROSS-REFERENCE TO RELATED APPLICATIONS

The present disclosure claims priority to Chinese Patent Application No. 202322663100.X, filed on Sep. 28, 2023, which is hereby incorporated by reference in its entirely.

### TECHNICAL FIELD

The present disclosure relates to the field of semiconductor device technologies, and in particular, to a semiconductor structure.

### BACKGROUND

As a preferred material for manufacturing next-generation transistors or semiconductor devices, a gallium nitride (GaN)-based semiconductor has many advantages over other semiconductors, and these transistors can be used in high-voltage and high-frequency applications. For example, a GaN-based semiconductor has a wide bandgap, so that a device made of these materials can have a higher breakdown electric field and can maintain firmness over a wide temperature range. A two-dimensional electron gas (2DEG) formed by a heterojunction structure based on the GaN generally has a higher electron mobility, so that devices manufactured using these structures can be used for power switches and amplification systems.

However, a GaN-based semiconductor device can often be broken down in advance due to factors such as gate leakage, buffer layer leakage, an electric field concentration effect of a gate close to the edge of a drain and the like, and the theoretical limit of the GaN material is not reached. Therefore, researches of a high-performance double-channel high electron mobility transistor (HEMT) devices with enhancement and high voltage resistance are of great significance to improve energy efficiency.

### SUMMARY

The present disclosure is provided in order to solve the technical problems. An embodiment of the present disclosure provides a semiconductor structure, including: a substrate, including a first region, a second region and a third region located between the first region and the second region; a channel structure formed on the substrate; and a first P-type buried layer located in the third region, where the first P-type buried layer extends along a direction parallel to a channel width.

Optionally, a thickness of the first P-type buried layer is less than or equal to a thickness of the substrate.

Optionally, the first P-type buried layer is located on a surface on a side, close to the channel structure, of the substrate.

Optionally, the first P-type buried layer is located in the substrate.

Optionally, the first P-type buried layer penetrates through the substrate along a thickness direction of the substrate

Optionally, there are a plurality of first P-type buried layers, and the plurality of first P-type buried layers are arranged at intervals along a direction parallel to a channel length.

Optionally, along the direction parallel to the channel length, a change mode of widths of sections of the plurality of first P-type buried layers includes at least one of following change modes: periodic change, gradual increase, gradual decrease, first increase and then decrease, or first decrease and then increase, the sections are perpendicular to a plane where the substrate is located.

Optionally, the semiconductor structure further includes a second P-type buried layer, located in the second region and connected to the first P-type buried layer.

Optionally, a thickness of the second P-type buried layer is not changed or decreased gradually along a direction from the first region to the second region.

Optionally, the second P-type buried layer is located on a surface on a side, close to the channel structure, of the substrate.

Optionally, the second P-type buried layer is located in the substrate.

Optionally, the second P-type buried layer penetrates through the substrate along a thickness direction of the substrate.

Optionally, there are a plurality of second P-type buried layers, and the plurality of second P-type buried layers are arranged at intervals along a direction parallel to a channel width.

Optionally, a width of a section of the second P-type buried layer is not changed or decreased gradually along a direction from the first region to the second region, and the section is parallel to a plane where the substrate is located.

Optionally, a maximum thickness of the second P-type buried layer is less than or equal to a maximum thickness of the first P-type buried layer.

Optionally, the semiconductor structure further includes a dielectric layer, located on a side, away from the substrate, of the channel structure.

Optionally, the semiconductor structure further includes a gate on a side, away from the substrate, of the channel structure, and a source and a drain which are located on both sides of the gate.

Optionally, a projection, on the substrate, of at least part of the gate is located in the third region, a projection, on the substrate, of the source is located in the first region, and a projection, on the substrate, of the drain is located in the second region.

Optionally, the channel structure further includes a channel layer and a barrier layer which are disposed sequentially on the substrate.

Optionally, a material of the substrate includes any one of SiC, Si, AlN or Al₂O₃.

### BRIEF DESCRIPTION OF THE DRAWINGS

The embodiments of the present disclosure are described in more details with reference to the accompanying drawings, and the above and other objectives, features, and advantages of the present disclosure will become more obvious. The drawings are used for a further understanding of the embodiments of the present disclosure, and constitute a part of the specification. The drawings and the embodiments are used to explain the present disclosure together, and do not constitute a limitation to the present disclosure. In the drawings, the same reference numbers represent the same parts or steps.

FIG. 1 is a schematic structural diagram of a semiconductor structure according to an embodiment of the present disclosure.

FIG. 2 is a schematic section view of the semiconductor structure according to the embodiment of FIG. 1 of the present disclosure.

FIG. 3 is a schematic structural diagram of a semiconductor structure according to another embodiment of the present disclosure.

FIG. 4 is a schematic structural diagram of a semiconductor structure according to another embodiment of the present disclosure.

FIG. 5a is a schematic structural diagram of a semiconductor structure according to another embodiment of the present disclosure.

FIG. 5b is a schematic section view of the semiconductor structure according to the embodiment of FIG. 5a of the present disclosure.

FIG. 5c is a schematic structural diagram of a semiconductor structure according to another embodiment of the present disclosure.

FIG. 6 is a schematic structural diagram of a semiconductor structure according to another embodiment of the present disclosure.

FIG. 7a and FIG. 7b are schematic section views of a semiconductor structure according to another embodiment of the present disclosure.

FIG. 8 is a schematic structural diagram of a semiconductor structure according to another embodiment of the present disclosure.

### DETAILED DESCRIPTIONS OF THE EMBODIMENTS

The following clearly and completely describes the technical solutions in the embodiments of the present disclosure with reference to the accompanying drawings in the embodiments of the present disclosure. Apparently, the described embodiments are a part rather than all of the embodiments of the present disclosure. All other embodiments obtained by a person of ordinary skill in the art based on the embodiments of the present disclosure without creative efforts shall fall within the protection scope of the present disclosure.

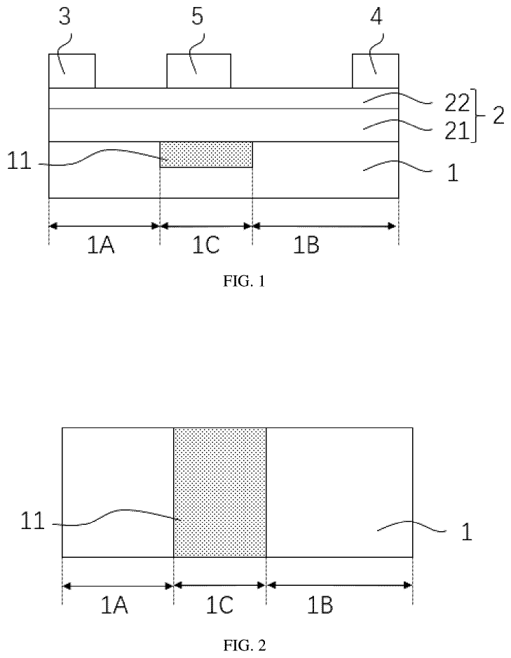

An embodiment of the present disclosure provides a semiconductor structure, as shown in FIG. 1 and FIG. 2. FIG. 1 is a schematic structural diagram of a semiconductor structure according to an embodiment of the present disclosure. FIG. 2 is a schematic section view of a semiconductor structure according to the embodiment of FIG. 1 of the present disclosure, the section is parallel to the substrate 1. The semiconductor structure includes: a substrate 1, including a first region 1A, a second region 1B and a third region 1C located between the first region 1A and the second region 1B; a channel structure 2 formed on the substrate 1; and a first P-type buried layer 11 located in the third region 1C. The first P-type buried layer 11 extends along a direction parallel to a channel width.

In the semiconductor structure according to the present embodiments, the first P-type buried layer 11 is disposed in the substrate 1, and the first P-type buried layer 11 is configured to deplete the two-dimensional electron gas in the channel structure 2, so as to achieve an enhancement-mode semiconductor structure. With this disposure, the problems of gate leakage, the electric field concentration effect of the gate close to the edge of the drain, and the like are avoided. In addition, tedious steps of manufacturing a P-type semiconductor layer above a channel structure in conventional method is avoided by disposing the first P-type buried layer 11 in the substrate 1, which simplifies the manufacturing method, and effectively improves the production efficiency.

A gate 5 is on a side, away from the substrate 1, of the channel structure 2, and a source 3 and a drain 4 are located on both sides of the gate 5. A projection, on the substrate 1, of at least part of the gate 5 is located in the third region 1C, a projection, on the substrate 1, of the source 3 is located in the first region 1A, and a projection, on the substrate 1, of the drain 4 is located in the second region 1B.

In the present embodiment, a material of the substrate 1 is SiC. In other embodiments, the material of the substrate 1 may also be any one of Si, AlN or Al₂O₃.

A channel structure 2 includes a channel layer 21 and a barrier layer 22 which are disposed sequentially on the substrate 1. Optionally, the material of the channel layer 21 and the barrier layer 22 is a group III nitride material. In the present embodiment, the material of the channel layer 21 and the barrier layer 22 are both GaN-based materials, the material of the channel layer 21 is GaN, and the material of the barrier layer 22 is AlGaN.

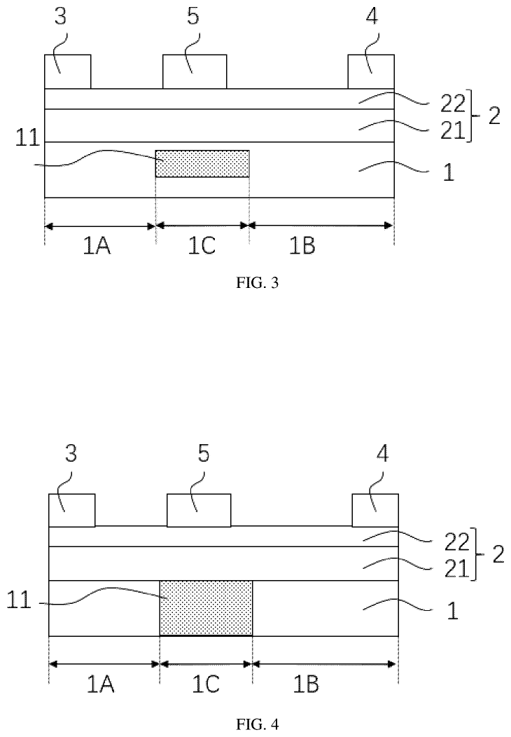

In the present embodiment, a thickness of the first P-type buried layer 11 is less than or equal to a thickness of the substrate 1. Optionally, the first P-type buried layer 11 is located on a surface on a side, close to the channel structure 2, of the substrate 1; or reference to FIG. 3, FIG. 3 is a schematic structural diagram of a semiconductor structure according to another embodiment of the present disclosure, the thickness of the first P-type buried layer 11 is less than the thickness of the substrate 1, and the first P-type buried layer 11 is located in the substrate 1; or reference to the FIG. 4, FIG. 4 is a schematic structural diagram of a semiconductor structure according to another embodiment of the present disclosure, the first P-type buried layer 11 penetrates through the substrate 1 along a thickness direction of the substrate 1.

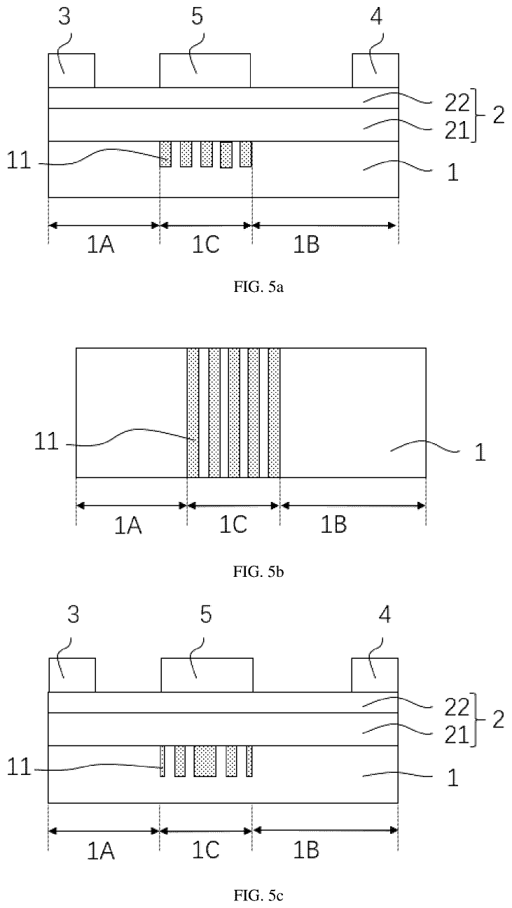

A semiconductor structure, according to another embodiment of the present disclosure, is approximately the same as the semiconductor structure according to the embodiment of FIG. 1 and FIG. 2, and the only difference is as following. As shown in FIG. 5a and FIG. 5b. FIG. 5a is a schematic structural diagram of a semiconductor structure according to another embodiment of the present disclosure. FIG. 5b is a schematic section view of the semiconductor structure according to the embodiment of FIG. 5a of the present disclosure. The section is parallel to the substrate 1. There are a plurality of first P-type buried layers, and the plurality of first P-type buried layers 11 are arranged at intervals along a direction parallel to a channel length.

Reference to FIG. 5c, FIG. 5c is a schematic structural diagram of a semiconductor structure according to another embodiment of the present disclosure. Optionally, along a direction parallel to a channel length, widths of sections of the plurality of first P-type buried layers 11 are increased at first and then decreased, and the section is perpendicular to the substrate 1. Optionally, in other embodiments, along a direction parallel to a channel length, a change mode of widths of sections of the plurality of first P-type buried layers 11 includes at least one of following change modes: periodic change, gradual increase, gradual decrease, first increase and then decrease, or first decrease and then increase, and the section is perpendicular to the substrate 1.

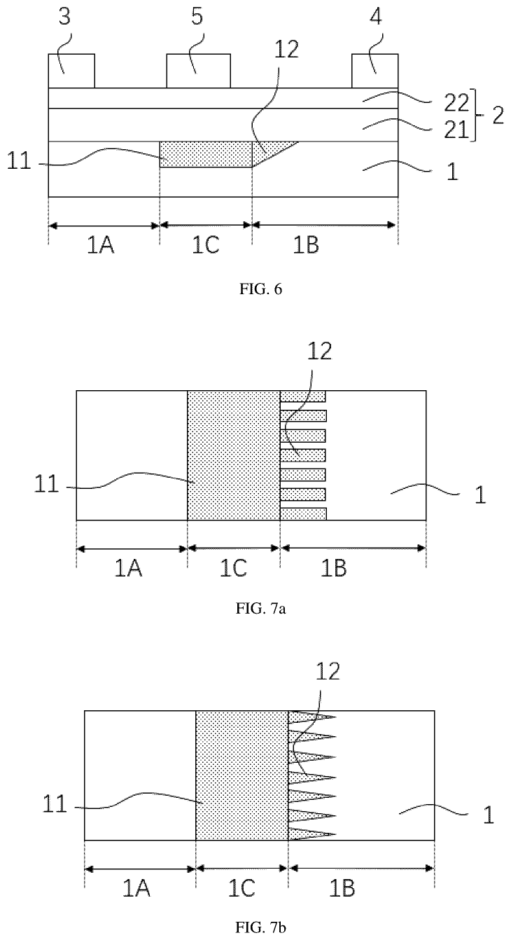

A semiconductor structure, according to another embodiment of the present disclosure, is approximately the same as the semiconductor structure according to the embodiment of FIG. 1 and FIG. 2, or FIG. 5a and FIG. 5b, and the only difference is as following. As shown in FIG. 6, FIG. 6 is a schematic structural diagram of a semiconductor structure according to another embodiment of the present disclosure. The semiconductor further includes a second P-type buried layer 12 located in the second region 1B, and the second P-type buried layer 12 is connected to the first P-type buried layer 11.

Optionally, a thickness of the second P-type buried layer 12 is not changed or decreased gradually along a direction from the first region 1A to the second region 1B.

The second P-type buried layer 12 in the present embodiment is located on a surface on a side, close to the channel structure 2, of the substrate 1. In other embodiments, the second P-type buried layer 12 may also be located in the substrate 1; or the second P-type buried layer 12 penetrates through the substrate 1 along a thickness direction of the substrate 1.

Optionally, a maximum thickness of the second P-type buried layer 12 is less than or equal to a maximum thickness of the first P-type buried layer 11 to improve the uniformity of the distribution of the gate electric field.

The configuration of the second P-type buried layer 12 may reduce the peak value of the electric field intensity of the gate 5 on the channel structure 2, and increase the total withstand voltage resistance of the semiconductor devices. The thickness of the second P-type buried layer 12 is gradually decreased, where a thickness of an end, close to the first P-type buried layer 11, of the second P-type buried layer 12 is the maximum, and the depletion of the two-dimensional electron gas in channel structure 2 is the most obvious, so that the peak value of the electric field here is suppressed to the greatest extent. Meanwhile, a thickness of a junction terminal in the direction close to the drain 4 is gradually decreased, so that the depletion degree of the two-dimensional electron gas in the direction close to the drain 4 is gradually decreased, and finally the concentration of the two-dimensional electron gas is recovered to the concentration without depletion. Therefore, electric field lines at the edge of the terminal cannot increase suddenly to a very dense density, and no new spikes of the electric field are introduced at the edge of the terminal. The electric field on the surface, between the gate 5 and the drain 4, of the barrier layer is in a smooth transition in a large range, the withstand voltage of the barrier layer semiconductor between the source and the drain is similar, which improves the breakage voltage of the devices.

A semiconductor structure, according to another embodiment of the present disclosure, is approximately the same as the semiconductor structure according to the embodiment of FIG. 6, and the only difference is as following. As shown in FIG. 7a and FIG. 7b, FIG. 7a and FIG. 7b are schematic section views of a semiconductor structure according to another embodiment of the present disclosure. The section is parallel to the substrate 1. there are a plurality of second P-type buried layers, and the plurality of second P-type buried layers 12 are arranged at intervals along a direction parallel to a channel width.

Optionally, a width of a section of the second P-type buried layer 12 is not changed or decreased gradually along a direction from the first region 1A to the second region 1B.

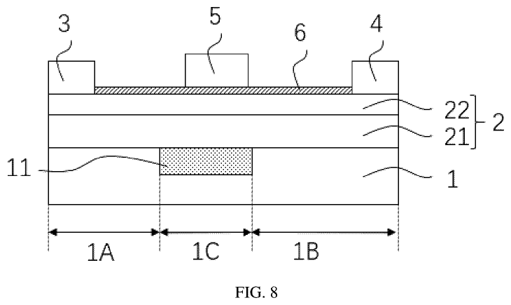

A semiconductor structure, according to another embodiment of the present disclosure, is approximately the same as the semiconductor structure according to any one of the above embodiments, and the only difference is as following. As shown in FIG. 8. FIG. 8 is a schematic structural diagram of a semiconductor structure according to another embodiment of the present disclosure. The semiconductor structure further includes a dielectric layer 6, located on a surface on a side, away from the substrate 1, of the channel structure 2, and the dielectric layer 6 is located between the gate 5 and the channel structure 2.

In the semiconductor structure according to the present embodiments, the first P-type buried layer is disposed in the substrate, and the first P-type buried layer is configured to deplete the two-dimensional electron gas in the channel structure, so as to achieve an enhancement-mode semiconductor structure. With this disposure, the problems of gate leakage, the electric field concentration effect of the gate close to the edge of the drain, and the like are avoided. In addition, tedious steps of manufacturing a P-type semiconductor layer above a channel structure in conventional method is avoided by disposing the first P-type buried layer in the substrate, which simplifies the manufacturing method, and effectively improves the production efficiency.

The basic principle of the present disclosure is described above in with reference to the specification embodiments. However, it should be noted that the advantages, benefits, effects, and the like mentioned in the present disclosure is merely example and are not limited, and these advantages, benefits, effects and the like are not considered to be the necessary for all embodiments of the present disclosure. In addition, the specific details disclosed above are only for purpose of examples and understanding easily, and are not be limited. The above details are not intended to limit the present disclosure to be achieved with the specific details necessarily described above.

The block diagrams of the devices, the apparatuses, the equipment and the systems are related in the present disclosure are only used as illustrative examples and do not need or imply that they must be connected, arranged or configured in the mode shown in the block diagrams. As those skilled in the art will appreciate that these devices, the apparatuses, the equipment and the systems may be connected, arranged and configured in any mode. The words such as “comprising”, “including”, “having” and the like are open terms, referring to “including, but not limited to”, and may be used interchangeably therewith. The words “or” and “and” as used herein refer to words “and/or” and may be used interchangeably, unless the context clearly indicates otherwise. The terms “such as” as used herein, refer to phrase “such as, but not limited to”, and may be used interchangeably therewith.

It should also be noted that in the apparatuses, devices, and method of the present disclosure, the various components or steps may be decomposed and/or recombined. The decomposition and/or recombination should be regarded as the equivalent scheme of the present disclosure.

The above description of the disclosed aspects is provided to enable any person skilled in the art to make or use the present disclosure. Various modifications to these aspects will be readily obvious to those skilled in the art, and the general principles defined herein can be applied to other aspects without departing from the scope of the present disclosure. Therefore, the present disclosure is not intended to be limited to the aspects shown herein, but rather to the broadest scope consistent with the principles and novel features disclosed herein.

The above description has been given for purposes of illustration and description. Furthermore, this description is not intended to limit the embodiments of the present disclosure to the forms disclosed herein. While various aspects and embodiments have been discussed above, those skilled in the art will recognize certain variations, modifications, changes, additions, and sub-combinations thereof.

What is claimed is:

1. A semiconductor structure, comprising:
a substrate, comprising a first region, a second region and a third region located between the first region and the second region;
a channel structure formed on the substrate; and
a first P-type buried layer located in the third region, wherein the first P-type buried layer extends along a direction parallel to a channel width.

2. The semiconductor structure according to claim 1, wherein a thickness of the first P-type buried layer is less than or equal to a thickness of the substrate.

3. The semiconductor structure according to claim 2, wherein the first P-type buried layer is located on a surface on a side, close to the channel structure, of the substrate.

4. The semiconductor structure according to claim 2, wherein the first P-type buried layer is located in the substrate.

5. The semiconductor structure according to claim 2, wherein the first P-type buried layer penetrates through the substrate along a thickness direction of the substrate.

6. The semiconductor structure according to claim 1, wherein there are a plurality of first P-type buried layers, and the plurality of first P-type buried layers are arranged at intervals along a direction parallel to a channel length.

7. The semiconductor structure according to claim 6, wherein along the direction parallel to the channel length, a change mode of widths of sections of the plurality of first P-type buried layers comprises at least one of following change modes: periodic change, gradual increase, gradual decrease, first increase and then decrease, or first decrease and then increase, the sections are perpendicular to a plane where the substrate is located.

8. The semiconductor structure according to claim 1, further comprising:
a second P-type buried layer, located in the second region and connected to the first P-type buried layer.

9. The semiconductor structure according to claim 8, wherein a thickness of the second P-type buried layer is not changed or decreased gradually along a direction from the first region to the second region.

10. The semiconductor structure according to claim 8, wherein the second P-type buried layer is located on a surface on a side, close to the channel structure, of the substrate.

11. The semiconductor structure according to claim 8, wherein the second P-type buried layer is located in the substrate.

12. The semiconductor structure according to claim 8, wherein the second P-type buried layer penetrates through the substrate along a thickness direction of the substrate.

13. The semiconductor structure according to claim 8, wherein there are a plurality of second P-type buried layers, and the plurality of the second P-type buried layers are arranged at intervals along a direction parallel to a channel width.

14. The semiconductor structure according to claim 13, wherein a width of a section of the second P-type buried layer is not changed or decreased gradually along a direction from the first region to the second region, and the section is parallel to a plane where the substrate is located.

15. The semiconductor structure according to claim 8, wherein a maximum thickness of the second P-type buried layer is less than or equal to a maximum thickness of the first P-type buried layer.

16. The semiconductor structure according to claim 1, further comprising:
a dielectric layer, located on a side, away from the substrate, of the channel structure.

17. The semiconductor structure according to claim 1, further comprising:
a gate on a side, away from the substrate, of the channel structure, and
a source and a drain which are located on both sides of the gate.

18. The semiconductor structure according to claim 17, wherein a projection, on the substrate, of at least part of the gate is located in the third region, a projection, on the substrate, of the source is located in the first region, and a projection, on the substrate, of the drain is located in the second region.

19. The semiconductor structure according to claim 1, wherein the channel structure comprises a channel layer and a barrier layer which are disposed sequentially on the substrate.

20. The semiconductor structure according to claim 1, wherein a material of the substrate comprises any one of SiC, Si, AlN or Al₂O₃.
